(19) United States
(12) Patent Application Publication
(10) Pub. No.: US 2007/0145506 A1
(43) Pub. Date: Jun. 28, 2007

(54) Assembly of image-sensing chip and circuit board with inward wire bonding

(76) Inventor: Feng Chen, Bothell, WA (US)

Correspondence Address: ROSENBERG, KLEIN & LEE, 3458 ELLICOTT CENTER DRIVE-SUITE 101, ELLICOTT CITY, MD, 21043, US

(21) Appl. No.: 11/318,905

(22) Filed: Dec. 28, 2005

(51) Int. Cl. H01L 31/0203

(52) U.S. Cl. 257/433

(57) ABSTRACT

An assembly of image-sensing chip and circuit boardwith inward wire bonding, including an image-sensing chip, a circuit board and a glass board. The circuit board is formed with a window and several wire bonding slots. An image-sensing chip is adhered to the circuit board. A wire bonding area is defined between the periphery of the image-sensing area and the bond pads of the image-sensing chip. By means of the wire bonding area, wires are inward bonded, that is, toward the image-sensing area from the bond pads through the wire bonding slots to the electric contacts of the circuit board. The glass board is disposed on the circuit board to block the window corresponding to the image-sensing area. Glue material is airtight filled around the image-sensing chip and the glass board and in the wire bonding slots of the circuit board for ensuring electric connection between the bond pads and the electric contacts.

### BACKGROUND OF THE INVENTION

The present invention is related to an assembly of image-sensing chip and circuit board with inward wire bonding. A wire bonding area is defined between the periphery of the image-sensing area and the bond pads of the image-sensing chip. By means of the wire bonding area, wires are inward bonded from the bond pads through the wire bonding slots of the circuit board to electrically connect the image-sensing chip with the circuit board.

FIG. 5. shows a conventional image sensor including a circuit board 70, a bank 71, an image sensing chip 72 and a glass board 73. The circuit board 70 has multiple leads 701. The image-sensing chip 72 is electrically connected with the leads 701 by means of laying out wires. The glass board 73 is adhered to the bank 71 to seal the image-sensing chip 72. Such structure is disadvantageous in that after packaged, the volume of the image sensor is much larger than the image-sensing chip 72. This is because that in order to achieve a good wire bonding effect during bond of the wires, the distance between the image-sensing chip 72 and the leads.701 is required not to smaller than a maximum distance. Accordingly, after packaged, the volume of the image sensor will be considerably enlarged. This limits the design of various portable electronic products such as cellular phones, PDA, internet cameras, etc.

The above shortcoming of the conventional image sensor can be improved by means of flip chip technique. FIG. 6 shows a conventional flip chip package structure of the image sensor. Such structure is made in such a manner that a bump 82 of each crystal 81 grows on a wafer. The crystal 81 with the bump 82 is soldered with the circuit contact 83 of the glass substrate 84. The inner face of the glass substrate 84 is formed with a circuit board 85 by means of photolithography. The manufacturing procedure for the flip chip package is quite complicated. The defects of the glue filled between the glass substrate 84 and the crystal 81 may affect the optical characteristics or reliability of the package. Therefore, the flip chip package has best electric performances and good heat radiation as well as smaller package volume. However, presently, it is still hard to manufacture such package of the image sensor and the manufacturing cost is relatively high. Also, the ratio of good products can be hardly enhanced.

Therefore, in consideration of manufacturing cost and technical issues, most of the existent packaging manufacturers still package the image sensor by means of bonding operation. It is therefore tried by the applicant to package the image sensor with small volume at low cost.

### SUMMARY OF THE INVENTION

It is therefore a primary object of the present invention to provide an assembly of image-sensing chip and circuit board with inward wire bonding, including an image-sensing chip, a circuit board and a glass board. The circuit board is formed with a window and several wire bonding slots. An image-sensing chip is adhered to the circuit board. A wire bonding area is defined between the periphery of the image-sensing area and the bond pads of the image-sensing chip. By means of the wire bonding area, wires are inward bonded, that is, toward the image-sensing area from the bond pads through the wire bonding slots to the electric contacts of the circuit board for transmission of electric signal. The size of the circuit board is approximately equal to the size of the image-sensing chip so that the volume of the package of the image-sensing chip is minified.

According to the above object, the assembly of image-sensing chip and circuit board with inward wire bonding of the present invention includes an image-sensing chip, a circuit board and a glass board.

The image-sensing chip has an image-sensing area and several bonding areas bonded around the image-sensing area. Multiple bond pads are arranged on each bonding area.

The circuit board is formed with a window and several wire bonding slots corresponding to the bond areas. The window has a specification approximately equal to a size of the image-sensing area. The wire bonding slot has a specification approximately equal to a size of the bonding area.

Multiple electric contacts are disposed on a surface of the circuit board between the window and the wire bonding slots. Multiple conductive circuits are arranged on the surface of the circuit board and connected with the electric contacts.

The image-sensing area of the image-sensing chip is aligned with the window of the circuit board for adhering the image-sensing chip to the circuit board. The bond pads of the bonding area of the image-sensing chip are aligned with the wire bonding slots. The bond pads are electrically connected to the electric contacts via golden wires. The wires are inward bonded, that is, toward the image-sensing area from the bond pads through the wire bonding slots to the electric contacts of the circuit board.

The glass board has a specification approximately equal to a size of the window. The glass board is disposed at the window of the circuit board right above the image-sensing area.

Glue material is airtight filled around the image-sensing chip and the glass board and in the wire bonding slots of the circuit board for ensuring electric connection between the bond pads and the electric contacts.

The present invention can be best understood through the following description and accompanying drawings wherein:

### BRIEF DESCRIPTION OF THE DRAWINGS

FIG. 1 is a side sectional view of the assembly of the present invention;

FIG. 2 is a top view of the circuit board of the present invention after etched;

FIG. 3 is a top view of the assembly of the present invention;

FIG. 4 is a sectional view showing that the lens unit is mounted on the assembly of the present invention according to FIG. 1 to form an image pickup module;

FIG. 5 is a sectional view of a conventional image sensor; and

FIG. 6 shows a conventional image sensor packaged by way of flip chip.

### DETAILED DESCRIPTION OF THE PREFERRED EMBODIMENTS

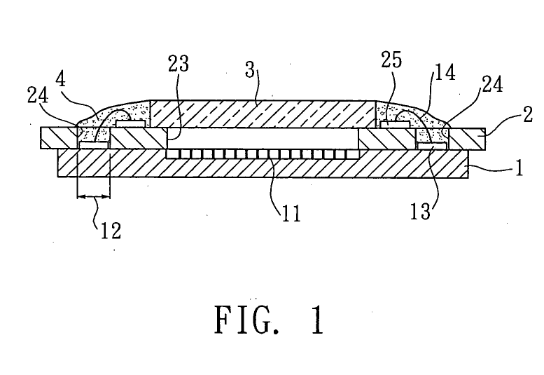

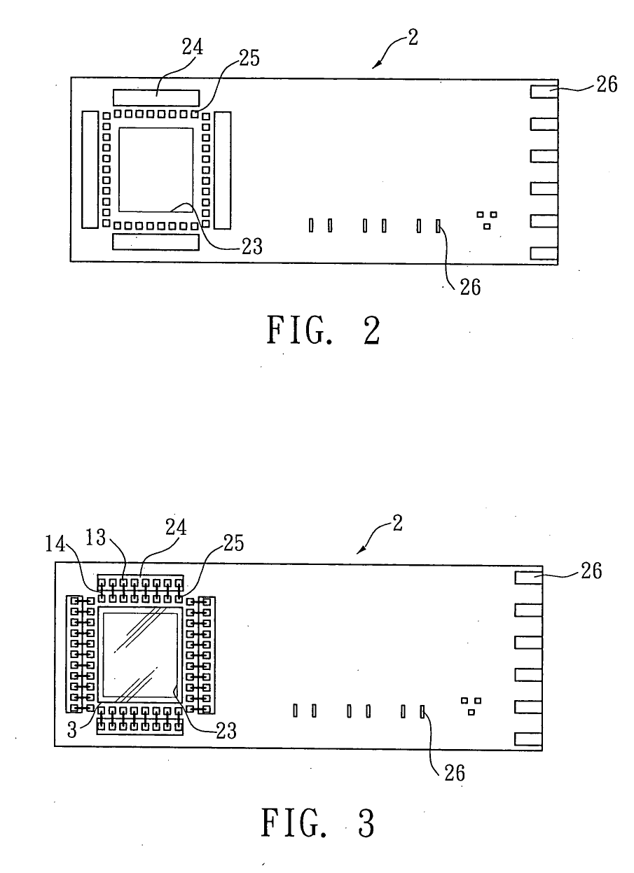

Please refer to FIGS. 1 to 4. The assembly of the present invention includes an image-sensing chip 1, a circuit board 2 and a glass board 3.

The image-sensing chip 1 has an image-sensing area 11 and several bonding areas 12 bonded around the image-sensing area 11. Multiple bond pads 13 are arranged on each bonding area 12.

The circuit board 2 is formed with a window 23 and several wire bonding slots 24 corresponding to the bonding areas 12. The window 23 has a specification approximately equal to the size of the image-sensing area 11. The wire bonding slot 24 has a specification approximately equal to the size of the bonding area 12. Multiple electric contacts 25 are disposed on the surface of the circuit board 2 between the window 23 and the wire bonding slots 24. In addition, multiple conductive circuits 26 are arranged on the surface of the circuit board 2 and connected with the electric contacts 25. The circuit board 2 is a soft circuit board.

The image-sensing area 11 of the image-sensing chip 1 is aligned with the window 23 of the circuit board 2 for adhering the image-sensing chip 1 to the circuit board 2. The bond pads 13 of the bonding area 12 of the image-sensing chip 1 are aligned with the wire bonding slots 24. The bond pads 13 are electrically connected to the electric contacts 25 via golden wires 14.

The glass board 3 has a specification approximately equal to the size of the window 23. The glass board 3 is disposed at the window 23 of the circuit board 2 right above the image-sensing area 11.

Glue material 4 is airtight filled around the image-sensing chip 1 and the glass board 3 and in the wire bonding slots 24 of the circuit board 2 for ensuring electric connection between the bond pads 13 and the electric contacts 25.

Referring to FIG. 3, a wire bonding area is defined between the periphery of the image-sensing area 11 and the bond pads 13 of the image-sensing chip 1. The wires 14 are inward (toward the image-sensing area 11 ) bonded from the bond pads 13 through the wire bonding slots 24 to the electric contacts 25 of the circuit board 2 for signal transmission. Such arrangement is advantageous in that the size and volume of the package of the image-sensing chip 1 are minified. The distance between the bond pads 13 and the electric contacts 25 is no longer required not to smaller than a maximum distance. The size of the circuit board 2 is approximately equal to the size of the image-sensing chip 1 so that the area of the circuit board 2 is greatly reduced. Accordingly, the cost for the package is lowered and better reliability of the package is achievable.

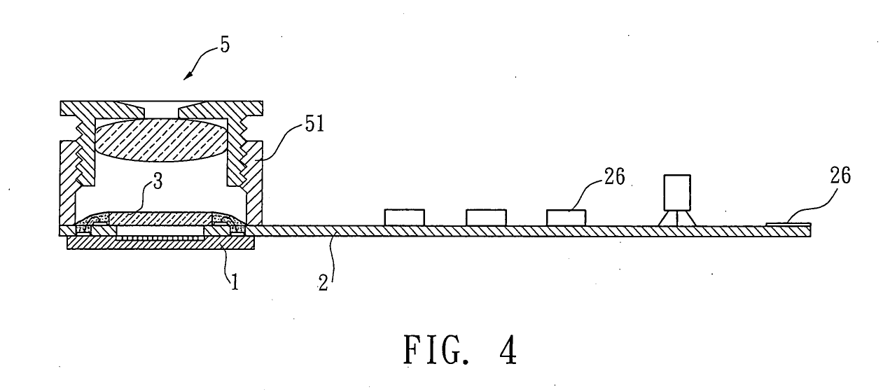

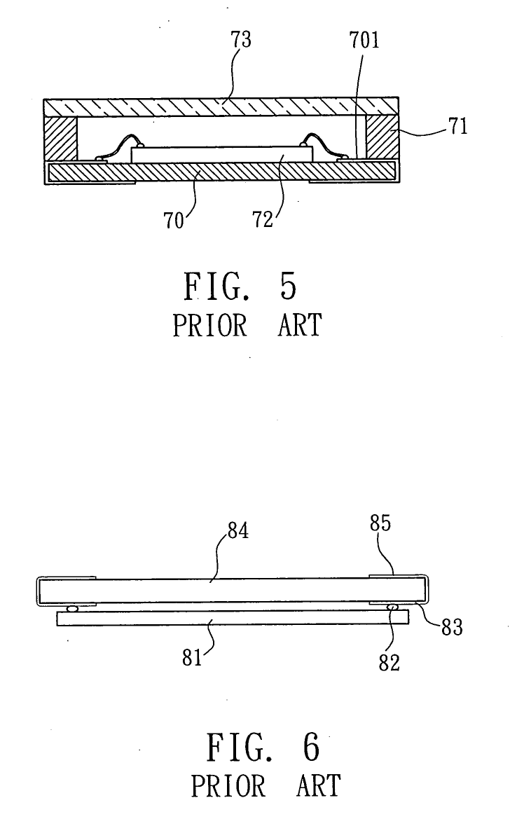

FIG. 4 shows an image pickup module composed of the assembly of the present invention and a lens unit 5. The lens holder 51 of the lens unit is laid on the circuit board 2 with the image-sensing chip 1 to cover the same. The image pickup module is applicable to various portable electronic products such as cellular phones, PDA, internet cameras, etc.

In comparison with the conventional packaging technique of the image sensor, the present invention can enhance production efficiency and lower requirement for equipments. Therefore, the price of the product can be greatly lowered. The present invention solves all the shortcomings existing in the conventional bonding measure and the expensive flip chip package.

The above embodiments are only used to illustrate the present invention, not intended to limit the scope thereof. Many modifications of the above embodiments can be made without departing from the spirit of the present invention.

What is claimed is:

1. An assembly of image-sensing chip and circuit board with inward wire bonding, comprising an image-sensing chip, a circuit board and a glass board, wherein:
the image-sensing chip has an image-sensing area and several bonding areas bonded around the image-sensing area, multiple bond pads being arranged on each bond area;
the circuit board is formed with a window and several wire bonding slots corresponding to the bonding areas, the window having a specification approximately equal to a size of the image-sensing area, the wire bonding slot having a specification approximately equal to a size of the bonding area;
multiple electric contacts are disposed on a surface of the circuit board between the window and the wire bonding slots, multiple conductive circuits being arranged on the surface of the circuit board and connected with the electric contacts;
the image-sensing area of the image-sensing chip is aligned with the window of the circuit board for adhering the image-sensing chip to the circuit board, the bond pads of the bond area of the image-sensing chip being aligned with the wire bonding slots, the bond pads being electrically connected to the electric contacts via golden wires; and
the glass board has a specification approximately equal to a size of the window, the glass board being disposed at the window of the circuit board right above the image-sensing area.

2. The assembly of image-sensing chip and circuit board with inward wire bonding as claimed in claim 1, wherein the glass board is glued with the circuit board to block the window.

3. The assembly of image-sensing chip and circuit board with inward wire bonding as claimed in claim 1, wherein the circuit board is soft circuit board.
